(19) United States
(12) Patent Application Publication
(10) Pub. No.: US 2016/0313644 A1
(43) Pub. Date: Oct. 27, 2016

(54) PATTERN FORMATION METHOD

(71) Applicant: Kabushiki Kaisha Toshiba, Minato-ku (JP)

(72) Inventors: Tomoya OORI, Kuwana (JP); Takehiro KONDOH, Yokkaichi (JP); Naoya KANEDA, Yokkaichi (JP); Eiichi SODA, Mie (JP)

(73) Assignee: Kabushiki Kaisha Toshiba, Minato-ku (JP)

(21) Appl. No.: 14/838,773

(22) Filed: Aug. 28, 2015

(30) Foreign Application Priority Data
Apr. 23, 2015 (JP) 2015-088519

(51) Int. Cl. G03F 7/20; G03F 7/36; G03F 7/32

(52) U.S. Cl. CPC G03F 7/2022; G03F 7/325; G03F 7/2024; G03F 7/36; G03F 7/2059; G03F 7/2002

(57) ABSTRACT

According to one embodiment, at first, a first resist film made from a first radiation sensitive composition is formed on a processing object film. Then, light exposure and development to the first resist film are performed to form a first resist pattern. Thereafter, an insolubilization process to insolubilize the first resist pattern to a solvent of a second radiation sensitive composition is performed. Then, a second resist film made from the second radiation sensitive composition is formed on the first resist pattern. Then, light exposure and development to the second resist film are performed to form a second resist pattern. At least one of the first radiation sensitive composition and the second radiation sensitive composition is made of a polymer compound resistant to oxygen that is present at the time of plasma etching.

### CROSS-REFERENCE TO RELATED APPLICATIONS

This application is based upon and claims the benefit of priority from Japanese Patent Application No. 2015-088519, filed on Apr. 23, 2015; the entire contents of which are incorporated herein by reference.

### FIELD

Embodiments described herein relate generally to a pattern formation method.

### BACKGROUND

A dual damascene method is a method in which a dual damascene pattern including a contact hole and a trench pattern is formed in an interlayer insulating film treated as a processing object film and a wiring material, such as Cu, is embedded in the dual damascene pattern all at one step. In general, the contact hole is formed in the processing object film by a lithography step and a dry etching step in the first round, and the trench pattern is formed in the processing object film by a lithography step and a dry etching step in the second round. Further, in recent years, in order to shorten the process steps and reduce the cost, there is also known a method in which a stepped structure is formed in a resist pattern by two lithography steps and a dual damascene pattern is formed by one dry etching.

However, along with advance in scaling, the thickness of a resist film has become smaller to prevent defects, such as a pattern fall. Consequently, a thickness of the resist film may be insufficient to perform transfer onto a processing object film. If the thickness of the resist film is insufficient, the processing object film cannot be processed to the end in some cases. Particularly, there is a case where formation of a trench pattern cannot be completed, and a wiring open defect is thereby generated.

### BRIEF DESCRIPTION OF THE DRAWINGS

FIGS. 1A to 1J are sectional views schematically showing an example of the sequence of a pattern formation method according to a first embodiment; and

FIGS. 2A to 2G are sectional views schematically showing an example of the sequence of a pattern formation method according to a second embodiment.

### DETAILED DESCRIPTION

In general, according to one embodiment, at first, a first resist film made from a first radiation sensitive composition is formed on a processing object film. Then, light exposure and development to the first resist film are performed to form a first resist pattern. Thereafter, an insolubilization process to insolubilize the first resist pattern to a solvent of a second radiation sensitive composition is performed. Then, a second resist film made from the second radiation sensitive composition is formed on the first resist pattern. Then, light exposure and development to the second resist film are performed to form a second resist pattern. At least one of the first radiation sensitive composition and the second radiation sensitive composition is made of a polymer compound resistant to oxygen that is present at the time of plasma etching.

Exemplary embodiments of a pattern formation method will be explained below in detail with reference to the accompanying drawings. The present invention is not limited to the following embodiments. The sectional views of a semiconductor device used in the following embodiments are schematic, and so the relationship between the thickness and width of each layer and/or the thickness ratios between respective layers may be different from actual states. Further, the film thicknesses illustrated hereinafter are mere examples, and they are not limiting.

### First Embodiment

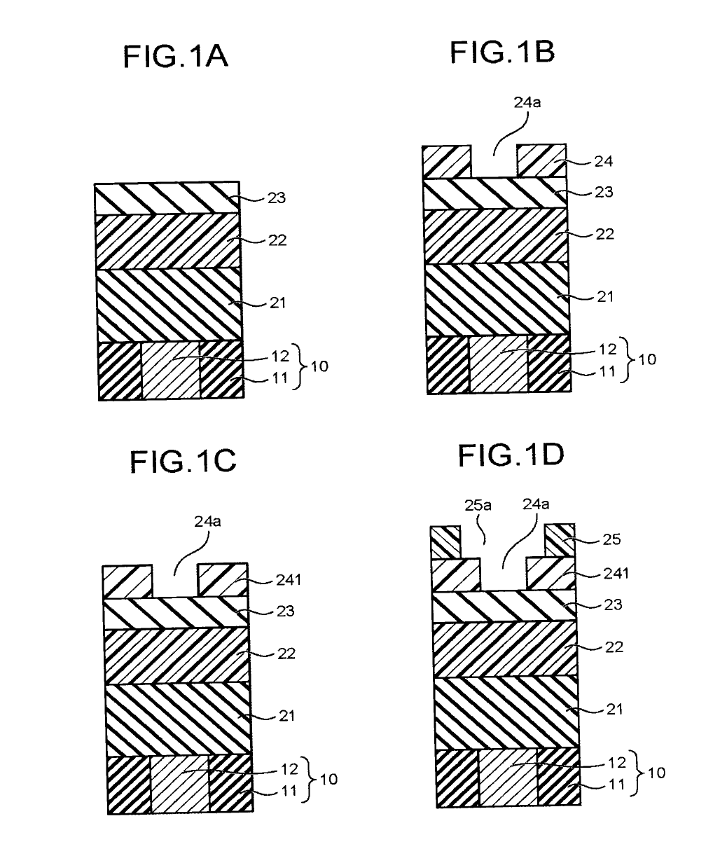

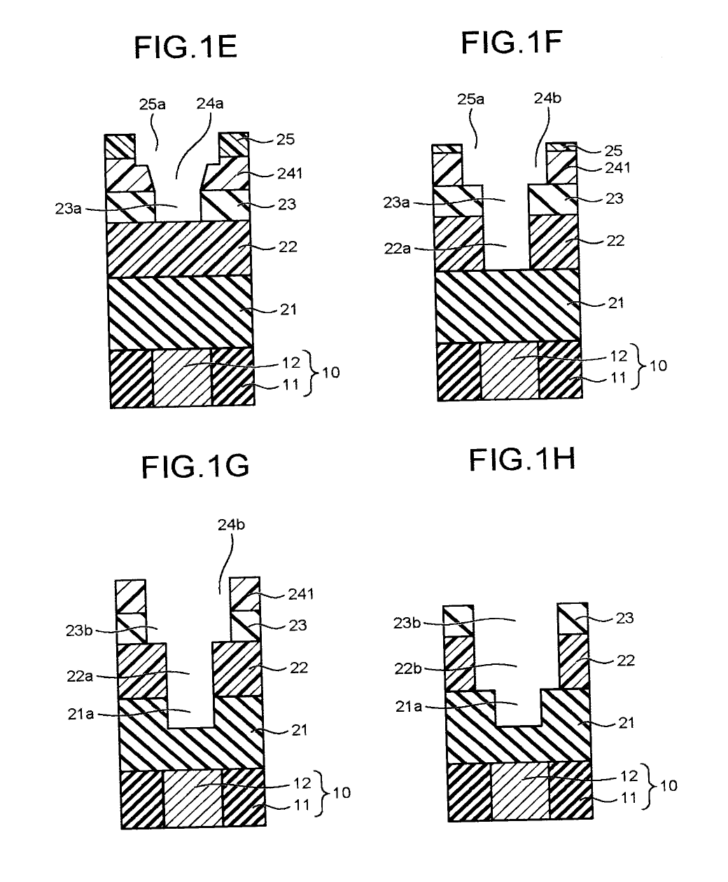

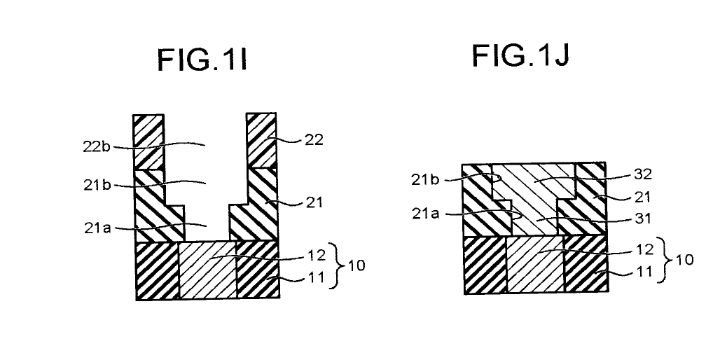

FIGS. 1A to 1J are sectional views schematically showing an example of the sequence of a pattern formation method according to a first embodiment. This pattern formation method will be explained with respect to a method forming a contact and a wiring connected to the contact in a semiconductor device by use of a dual damascene method.

At first, as shown in FIG. 1A, an interlayer insulating film 21, a first mask film 22, and a second mask film 23 are formed on a wiring layer 10. For example, the wiring layer 10 is composed of an interlayer insulating film 11 and a wiring pattern 12 formed therein, and is provided above a substrate (not shown).

The interlayer insulating film 21 is treated as a processing object film in which a contact connected to the wiring pattern 12 and a wiring pattern connected to this contact will be embedded. A tetraethoxysilane (TEOS) film or SiO₂ film is used as the interlayer insulating film 21, for example. A thickness of this film may be set to 200 nm, for example.

The first mask film 22 will be used as a mask for processing the interlayer insulating film 21 by etching. An organic film, such as an SoC (Spin on Carbon) film, for example, is used as the first mask film 22. A thickness of this film may be set to 200 nm, for example.

The second mask film 23 will be used as a mask for processing the first mask film 22 and the interlayer insulating film 21 by etching. An inorganic film, such as an SoG (Spin on Glass) film, for example, is used as the second mask film 23. A thickness of this film may be set to 50 nm, for example.

Then, as shown in FIG. 1B, a first resist film is formed on the second mask film 23. The first resist film may be formed by applying a first radiation sensitive composition by use of a coating method or the like, for example. A thickness of this film may be set to 200 nm, for example. The first radiation sensitive composition may be made of a negative type resist, which is used in ordinary lithography steps. Further, the first radiation sensitive composition is one for which an organic solvent is used as a developing solution at the time of its development. Furthermore, the first radiation sensitive composition preferably has a composition such that, when being cured, it is insolubilized to the solvent of a second radiation sensitive composition described later.

Thereafter, the first resist film is patterned by use of a light exposure technique and a development technique to form a first resist pattern 24. In this example, a contact hole pattern (which will be referred to as a hole pattern) 24a is formed. More specifically, a latent image is formed in the first resist film by use of a light exposure technique. This light exposure may employ radiation rays, such as electromagnetic waves having a wavelength within the visible light region, for example. Then, a development process using an organic solvent is performed, so that a pattern composed of remaining portions, which have been irradiated with radiation rays, is formed. A developing solution for this may be made of an ether, such as diethyl ether, tetrahydrofuran, or anisole; a ketone, such as acetone, methylisobutylketone, 2-heptanone, or cyclohexanone; or an ester, such as butyl acetate or isoamyl acetate, for example. Further, the developing solution may be made of a mixture of a plurality of different ones of the organic solvents set out above, which is prepared by selecting the optimum ones to an employed resist. The development is performed by immersing the first resist film in the developing solution for a predetermined time. Consequently, the first resist pattern 24 including the hole pattern 24a having a predetermined diameter is formed.

Then, as shown in FIG. 1C, the first resist pattern 24 is insolubilized to the solvent of the second radiation sensitive composition, and the first resist pattern 241 is thereby formed. This insolubilization process may be exemplified by a heat process or an energy ray irradiation process. The heat process may be exemplified by a process of heating the substrate including the first resist pattern 24 at 200° C. for a predetermined time. Further, the energy ray irradiation process may be exemplified by a process of irradiation with energy rays, such as electron beam or ultraviolet rays. Consequently, the first resist pattern 241 in a cured state is obtained. The cured first resist pattern 241 exhibits insolubility to the solvent of the second radiation sensitive composition described later.

Thereafter, as shown in FIG. 1D, a second resist film is formed on the insolubilized first resist pattern 241. The second resist film may be formed by applying the second radiation sensitive composition by use of a coating method or the like. The second radiation sensitive composition is a negative type resist in which a radiation sensitive polymer compound resistant to oxygen that is present at the time of plasma etching is dissolved as a solute in at least one solvent selected from the group consisting of cyclohexanone, PGMEA (PropyleneGlycol Monomethyl Ether Acetate), and PGME (PropyleneGlycol Monomethyl Ether), for example. The radiation sensitive polymer compound resistant to oxygen that is present at the time of plasma etching contains Si or metal in the polymer main chain. The metal is preferably an element that does not affect or can hardly affect the operation of the semiconductor device even if it is diffused into the semiconductor device. Such a metal may be exemplified by Ti, W, Al, Ta, Hf, Zr or Mo. The second radiation sensitive composition is preferably one for which an organic solvent is used as a developing solution at the time of its development. The thickness of the second resist film may be set to 200 nm, for example. Here, since the first resist pattern 241 has been insolubilized to the solvent of the second radiation sensitive composition, the first resist pattern 241 cannot be dissolved by the solvent of the second radiation sensitive composition when the second resist film is formed.

Then, the second resist film is patterned by use of a light exposure technique and a development technique, and a second resist pattern 25 is thereby formed. In this example, a trench pattern 25a for embedding a wiring pattern is formed. The trench pattern 25a is formed such that it is connected to the hole pattern 24a formed in the first resist pattern 241. The trench pattern 25a may be an isolated pattern or may be part of line-and-space patterns. In a case where the trench pattern 25a is formed as part of line-and-space patterns, trench patterns 25a extend in a predetermined direction and arranged at predetermined intervals in a direction intersecting with the extending direction. Here, when the trench patterns 25a are formed in a line-and-space form, they are not limited to straight line patterns. A form that may be regarded as the line-and-space patterns is of a type in which a plurality of non-straight wiring lines, such as lead-out wiring lines, routing wiring lines, or U-shaped wiring lines, are arranged in a direction intersecting with their extending direction. Further, even if line patterns extending in parallel are connected to each other by connecting patterns, the portions excluding the connecting patterns may be regarded as line patterns.

More specifically, a latent image is formed in the second resist film by use of a light exposure technique. This light exposure may employ radiation rays, such as electromagnetic waves having a wavelength within the visible light region, for example. Then, a development process using an organic solvent is performed, so that a pattern composed of remaining portions, which have been irradiated with radiation rays, is formed. The developing solution for this may be made of an ether, such as diethyl ether, tetrahydrofuran, or anisole; a ketone, such as acetone, methylisobutylketone, 2-heptanone, or cyclohexanone; or an ester, such as butyl acetate or isoamyl acetate, for example. Further, the developing solution may be made of a mixture of a plurality of different ones of the organic solvents set out above, which is prepared by selecting the optimum ones to an employed resist. The development is performed by immersing the second resist film in the developing solution for a predetermined time. Consequently, the second resist pattern 25 including the trench pattern 25a is formed.

As a result of the processes described above, a resist pattern is formed on the second mask film 23 such that the resist pattern has a stepped structure composed of the first resist pattern 241 formed with the hole pattern 24a and the second resist pattern 25 including the trench pattern 25a arranged on the hole pattern 24a. Thereafter, the processing object film is processed, through the resist pattern having this stepped structure and serving as a mask, by use of dry etching. Next, the subsequent steps will be explained in detail.

As shown in FIG. 1E, plasma etching using a gas containing a fluorocarbon based gas as a main component is performed, through the first resist pattern 241 serving as a mask, so that the second mask film 23 is processed. The plasma etching may be exemplified by an RIE (Reactive Ion Etching) method or the like. Consequently, the hole pattern 24a of the first resist pattern 241 is transferred onto the second mask film 23. Here, while a hole pattern 23a is being formed by transfer onto the second mask film 23, the trench pattern 25a of the second resist pattern 25 is hardly transferred onto the first resist pattern 241. This is due to the difference in composition between the first resist pattern 241 and the second resist pattern 25, such that the first resist pattern 241 is less etchable than the second resist pattern 25, during the etching using a fluorocarbon based gas.

Then, as shown in FIG. 1F, plasma etching using a gas containing oxygen as a main component is performed, through the second mask film 23 serving as a mask, so that a hole pattern 22a is formed by transfer onto the first mask film 22. At this time, since the second resist pattern 25 contains Si or metal in the polymer main chain, it is higher in etching resistance to the gas containing oxygen as a main component. Accordingly, part of the first resist pattern 241 exposed at the bottom of the trench of the second resist pattern 25 is processed faster than the second resist pattern 25 and is thereby removed. In other words, plasma etching is performed, through the second resist pattern 25 as a mask, so that a trench pattern 24b is formed by transfer onto the first resist pattern 241. As a result, a structure is obtained such that the second mask film 23 including the hole pattern 23a and the first resist pattern 241 and the second resist pattern 25 respectively including the trench patterns 24b and 25a are arranged on the first mask film 22 including the hole pattern 22a.

Thereafter, as shown in FIG. 1G, plasma etching using a gas containing a fluorocarbon based gas as a main component is performed, through the first resist pattern 241 and the second resist pattern 25 respectively including the trench patterns 24b and 25a and serving as a mask, so that a trench pattern 23b is formed by transfer onto the second mask film 23. Consequently, a structure is obtained such that the second mask film 23 formed with the trench pattern 23b and the first resist pattern 241 including the trench pattern 24b are arranged on the first mask film 22 including the hole pattern 22a. Further, when the trench pattern 23b is formed by transfer onto the second mask film 23, the interlayer insulating film 21 treated as the processing object film is etched through the first mask film 22 serving as a mask. Thus, a hole pattern 21a is also formed by transfer onto the interlayer insulating film 21. However, this transfer is performed only in a period during which the second mask film 23 is being processed, and so it becomes half etching that etches the interlayer insulating film 21 only down to the middle of its thickness.

Then, as shown in FIG. 1H, plasma etching using a gas containing oxygen as a main component is performed, through the second mask film 23 including the trench pattern 23b and serving as a mask, so that a trench pattern 22b is formed by transfer onto the first mask film 22. At this time, the first resist pattern 241 and the second resist pattern 25 are removed, while the first mask film 22 is being processed. As a result, a structure is obtained such that the first mask film 22 and the second mask film 23 respectively formed with the trench patterns 22b and 23b are arranged on the interlayer insulating film 21 including the hole pattern 21a formed by the half etching.

Thereafter, as shown in FIG. 1I, plasma etching using a gas containing a fluorocarbon based gas as a main component is performed, through the first mask film 22 and the second mask film 23 respectively including the trench patterns 22b and 23b and serving as a mask, so that a trench pattern 21b is formed by transfer onto the interlayer insulating film 21. At this time, the hole pattern 21a formed in advance is processed simultaneously with formation of the trench pattern 21b, so that it reaches the lower surface of the interlayer insulating film 21 earlier than the trench pattern 21b. The plasma etching is finished at the time point when the hole pattern 21a reaches the substrate, so that the hole pattern 21a becomes a contact hole and the trench pattern 21b becomes a trench.

Then, as shown in FIG. 1J, a seed film (not shown) made of a conductive material, such as Cu, is formed in a conformal state on the interlayer insulating film 21, by use of a PVD (Physical Vapor Deposition) method or CVD (Chemical Vapor Deposition) method. Thereafter, a conductive material, such as Cu, is formed on the seed film by use of a plating method. Then, part of the conductive material film present above the upper surface of the interlayer insulating film 21 is removed by use of a CMP (Chemical Mechanical Polishing) method. Consequently, a contact 31 is formed from the conductive material embedded in the contact hole 21a, and a wiring pattern 32 is formed from the conductive material embedded in the trench 21b.

In this example, the etching shown in FIG. 1G is performed only in a period of processing the second mask film 23, and so the hole pattern 21a is formed by half etching that etches the interlayer insulating film 21 only down to the middle of its thickness. However, this etching may be performed to completely penetrate the interlayer insulating film 21 in the thickness direction.

According to the first embodiment, the organic first mask film 22 and the inorganic second mask film 23 are formed on the processing object film, and the first resist pattern 24 including the hole pattern 24a is formed on the second mask film 23. The first resist pattern 24 is insolubilized, and then the second resist pattern 25 including the trench pattern 25a is formed on the insolubilized first resist pattern 241. The second resist pattern 25 is made of a polymer compound containing Si or metal in the polymer main chain. Then, plasma etching using a gas containing a fluorocarbon based gas as a main component and plasma etching using a gas containing oxygen as a main component are alternately performed.

Consequently, it is possible to form the hole pattern 21a and the trench pattern 21b connected to the hole pattern 21a in the processing object film with high yield. Further, the method according to the first embodiment includes the second resist pattern 25, which has a thickness sufficient to etch the processing object film. Consequently, it is also possible to form the trench pattern in the interlayer insulating film 21, while preventing generation of a wiring open defect.

### Second Embodiment

In the first embodiment, the first resist pattern and the second resist pattern are stacked on the mask films to perform pattern formation. Further, the first resist pattern is made of the first radiation sensitive composition that contains neither Si nor metal in the polymer main chain, and the second resist pattern is made of the second radiation sensitive composition that contains Si or metal in the polymer main chain. In the second embodiment, an explanation will be given of a case where the first resist pattern is made of the second radiation sensitive composition that contains Si or metal in the polymer main chain, and the second resist pattern is made of the first radiation sensitive composition that contains neither Si nor metal in the polymer main chain.

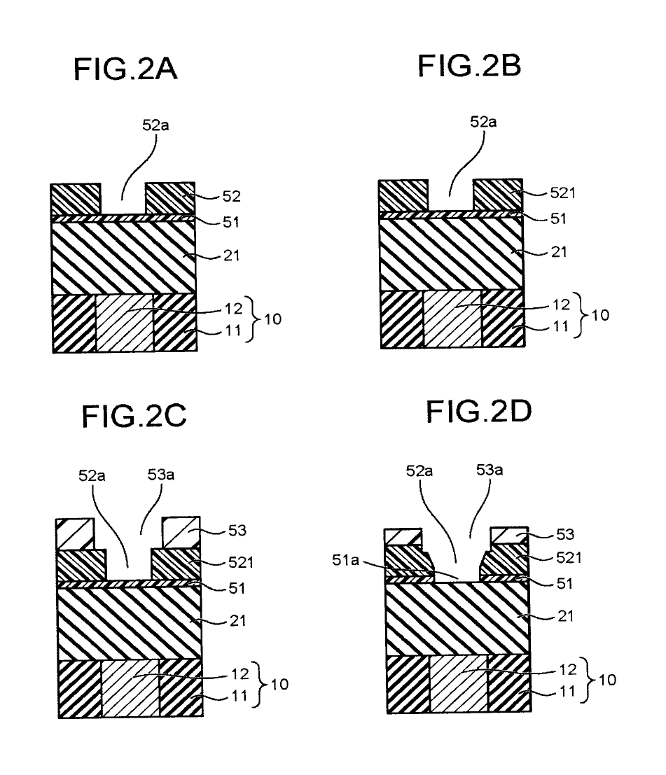

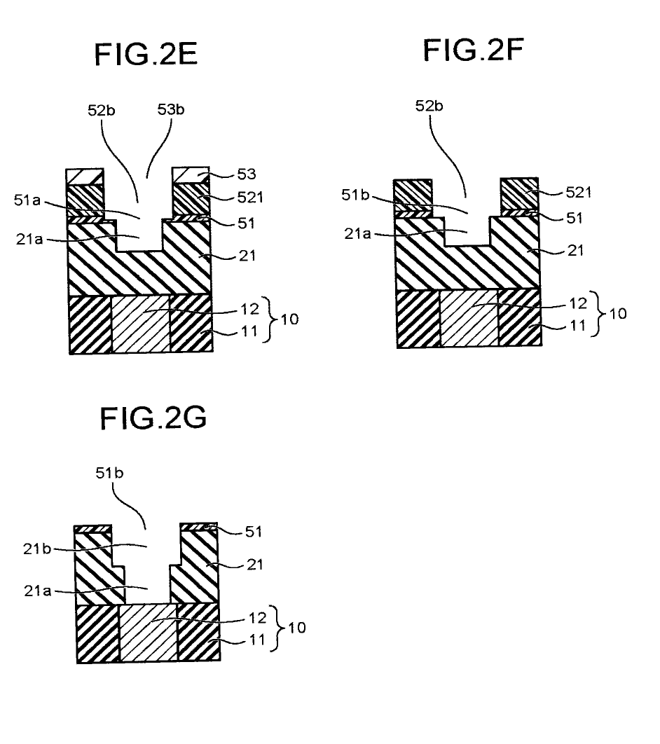

FIGS. 2A to 2G are sectional views schematically showing an example of the sequence of a pattern formation method according to the second embodiment. This pattern formation method will be explained with respect to a method for forming a contact and a wiring connected to the contact in a semiconductor device by use of a dual damascene method.

At first, as shown in FIG. 2A, an interlayer insulating film 21 and an antireflection film 51 are formed on a wiring layer 10. The wiring layer 10 and the interlayer insulating film 21 are the same as those described in the first embodiment. The thickness of the interlayer insulating film 21 may be set to 200 nm, for example. The antireflection film 51 is made of a material containing a light absorptive substance and a radiation sensitive polymer compound, and it will also serve as a mask for processing the interlayer insulating film 21. The thickness of the antireflection film 51 may be set to 90 nm, for example.

Then, a first resist film is formed on the antireflection film 51. The first resist film may be formed by applying the second radiation sensitive composition described in the first embodiment, by use of a coating method or the like. The second radiation sensitive composition is a negative type resist containing a radiation sensitive polymer compound resistant to oxygen that is present at the time of plasma etching. The radiation sensitive polymer compound resistant to oxygen that is present at the time of plasma etching contains Si or metal in the polymer main chain. The metal may be exemplified by Ti, W, Al, Ta, Hf, Zr or Mo. The second radiation sensitive composition is preferably one for which an organic solvent is used at the time of its development. The thickness of the first resist film may be set to 200 nm.

Thereafter, the first resist film is patterned by use of a light exposure technique and a development technique, so that a first resist pattern 52 is formed. In this example, a hole pattern 52a is formed. More specifically, a latent image is formed in the first resist film by use of a light exposure technique. This light exposure may employ radiation rays, such as electromagnetic waves having a wavelength within the visible light region, for example. Then, a development process using an organic solvent is performed, so that a pattern composed of remaining portions, which have been irradiated with radiation rays, is formed. The developing solution for this may be made of an ether, such as diethyl ether, tetrahydrofuran, or anisole; a ketone, such as acetone, methylisobutylketone, 2-heptanone, or cyclohexanone; or an ester, such as butyl acetate or isoamyl acetate, for example. Further, the developing solution may be made of a mixture of a plurality of different ones of the organic solvents set out above, which is prepared by selecting the optimum ones to an employed resist. The development is performed by immersing the first resist film in the developing solution for a predetermined time. Consequently, the first resist pattern 52 including the hole pattern 52a having a predetermined diameter is formed.

Then, as shown in FIG. 2B, the first resist pattern 52 is insolubilized to the solvent of the first radiation sensitive composition, and a first resist pattern 521 is thereby formed. This insolubilization process may be exemplified by a heat process or an energy ray irradiation process, as in the first embodiment.

Thereafter, as shown in FIG. 2C, a second resist film is formed on the insolubilized first resist pattern 521. The second resist film may be formed by applying the first radiation sensitive composition described in the first embodiment, by use of a coating method or the like. The first radiation sensitive composition is a negative type resist in which a radiation sensitive polymer compound is dissolved as a solute in at least one solvent selected from the group consisting of cyclohexanone, PGMEA, and PGME, for example. The first radiation sensitive composition is also preferably one for which an organic solvent is used at the time of its development. The thickness of the second resist film may be set to 200 nm.

Then, the second resist film is patterned by use of a light exposure technique and a development technique, so that a second resist pattern 53 is formed. In this example, a trench pattern 53a for embedding a wiring pattern is formed. The trench pattern 53a is formed such that it is connected to the hole pattern 52a formed in the first resist pattern 521. The trench pattern 53a may be an isolated pattern or may be part of line-and-space patterns.

As a result of the processes described above, a resist pattern is formed on the antireflection film 51 such that the resist pattern has a stepped structure composed of the first resist pattern 521 formed with the hole pattern 52a and the second resist pattern 53 including the trench pattern 53a arranged above the hole pattern 52a. Thereafter, the processing object film is processed, through the resist pattern having this stepped structure and serving as a mask, by use of dry etching. Next, the subsequent steps will be explained in detail.

Thereafter, as shown in FIG. 2D, plasma etching using a gas containing oxygen as a main component is performed, through the first resist pattern 521 serving as a mask, so that a hole pattern 51a is formed by transfer onto the antireflection film 51. Here, part of the first resist pattern 521 exposed at the bottom of the trench of the second resist pattern 53 is removed.

Then, as shown in FIG. 2E, plasma etching using a gas containing a fluorocarbon based gas as a main component is performed, through the antireflection film 51 formed with the hole pattern 51a and serving as a mask, so that a hole pattern 21a is formed by transfer onto the interlayer insulating film 21 treated as a processing object film. At this time, since the first resist pattern 521 contains Si or metal in the polymer main chain, it is lower in resistance to the gas containing a fluorocarbon based gas as a main component, as compared with the second resist pattern 53. Accordingly, part of the first resist pattern 521 exposed at the bottom of the trench of the second resist pattern 53 is processed faster than the second resist pattern 53 and is thereby removed. Thus, a trench pattern 52b is formed by transfer onto the first resist pattern 521. Here, the etching is stopped at the timing when part of the first resist pattern 521 exposed at the bottom of the trench of the second resist pattern 53 is removed, so that etching to the interlayer insulating film 21 is stopped with half etching. As a result, a structure is obtained such that the antireflection film 51 including the hole pattern 51a and the first resist pattern 521 and the second resist pattern 53 respectively including the trench patterns 52b and 53b are arranged on the interlayer insulating film 21 including the hole pattern 21a formed by transfer.

Thereafter, as shown in FIG. 2F, plasma etching using a gas containing oxygen as a main component. is performed, through the first resist pattern 521 and the second resist pattern 53 respectively including the trench patterns 52b and 53b and serving as a mask, so that a trench pattern 51b is formed by transfer onto the antireflection film 51. As a result, a structure is obtained such that the antireflection film 51 formed with the trench pattern 51b and the first resist pattern 521 formed with the trench pattern 52b are arranged on the interlayer insulating film 21 including the hole pattern 21a formed by the half etching. At this time, the second resist pattern 53 has already been consumed and thereby vanished, because of the transfer processes for forming the hole pattern 51a and the trench pattern 51b in the antireflection film 51.

Then, as shown in FIG. 2G, plasma etching using a gas containing a fluorocarbon based gas as a main component is performed, through the first resist pattern 521 including the trench pattern 52b and the antireflection film 51 including the trench pattern 51b, which serve as a mask, so that a trench pattern 21b is formed by transfer onto the interlayer insulating film 21. At this time, the hole pattern 21a formed in advance is processed simultaneously with formation of the trench pattern 21b, so that it reaches the lower surface of the interlayer insulating film 21 earlier than the trench pattern 21b. The plasma etching is finished at the time point when the hole pattern 21a reaches the substrate, so that the hole pattern 21a becomes a contact hole and the trench pattern 21b becomes a trench. Here, since the first resist pattern 521 contains Si or metal in the polymer main chain, it is lower in etching resistance to a fluorocarbon based gas. Consequently, this pattern is removed, while the interlayer insulating film 21 is being processed.

Thereafter, the antireflection film 51 is exposed to plasma using a gas containing oxygen as a main component, so that the antireflection film 51 is removed. Then, the process shown in FIG. 1J, of the first embodiment is performed, so that a contact 31 is formed from a conductive material embedded in the contact hole 21a, and a wiring pattern 32 is formed from the conductive material embedded in the trench 21b.

The second embodiment provides effects the same as those of the first embodiment.

In the embodiments described above, the explanations have been given of a case where one of the first resist pattern 24 or 52 and the second resist pattern 25 or 53 is made of the first radiation sensitive composition that contains neither Si nor metal in the polymer main chain, and the other is made of the second radiation sensitive composition that contains Si or metal in the polymer main chain. However, both of the first resist pattern 24 or 52 and the second resist pattern 25 or 53 may be made of a radiation sensitive composition that contains Si or metal in the polymer main chain. In this case, the first resist pattern 24 or 52 and the second resist pattern 25 or 53 may be set different from each other in the concentration (content) of Si or metal. If the second resist pattern 25 or 53 is set higher in the concentration of Si or metal than the first resist pattern 24 or 52, the same pattern formation method as the first embodiment may be applied. Further, if the first resist pattern 24 or 52 is set higher in the concentration of Si or metal than the second resist pattern 25 or 53, the same pattern formation method as the second embodiment may be applied.

Further, the pattern formation methods described above may be used for forming contacts or vias and wirings in a nonvolatile semiconductor memory device, such as a NAND type flash memory, or a nonvolatile memory device, such as a ReRAM.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A pattern formation method comprising:
forming a first resist film made from a first radiation sensitive composition on a processing object film;
performing light exposure and development to the first resist film to form a first resist pattern;
performing an insolubilization process to insolubilize the first resist pattern to a solvent of a second radiation sensitive composition;
forming a second resist film made from the second radiation sensitive composition on the first resist pattern; and
performing light exposure and development to the second resist film to form a second resist pattern,
wherein at least one of the first radiation sensitive composition and the second radiation sensitive composition is made of a polymer compound resistant to oxygen that is present at the time of plasma etching.

2. The pattern formation method according to claim 1, wherein the polymer compound resistant to oxygen that is present at the time of plasma etching includes Si or metal in a polymer main chain.

3. The pattern formation method according to claim 2, wherein the metal is at least one element selected from the group consisting of Ti, W, Al, Ta, Hf, Zr and Mo.

4. The pattern formation method according to claim 1, wherein, in the performing of development of the first resist film and the second resist film, the development of the first resist film and the development of the second resist film are performed by use of an organic solvent.

5. The pattern formation method according to claim 4, wherein the organic solvent includes at least one of diethyl ether, tetrahydrofuran, anisole, acetone, methylisobutylketone, 2-heptanone, cyclohexanone, butyl acetate, and isoamyl acetate.

6. The pattern formation method according to claim 1, wherein the insolubilization process is a process of heating the first resist pattern or a process of irradiating the first resist pattern with energy rays.

7. The pattern formation method according to claim 6, wherein the energy rays are an electron beam or UV light.

8. The pattern formation method according to claim 1, wherein the solvent of the second radiation sensitive composition is at least one solvent selected from the group consisting of cyclohexanone, PGMEA, and PGME.

9. The pattern formation method according to claim 1, wherein the first resist film and the second resist film are made of a negative type resist.

10. The pattern formation method according to claim 1, wherein the first resist pattern is formed of the first resist film provided with a hole pattern, and
the second resist pattern is formed of a second resist film provided with a trench pattern connected to the hole pattern.

11. The pattern formation method according to claim 1 further comprising:
forming an organic first mask film and an inorganic second mask film on the processing object film, before the forming of the first resist film; and
forming an hole pattern and a trench pattern connected to the hole pattern in the processing object film by plasma etching, after the forming of the second resist pattern,
wherein, in the forming of the hole pattern and the trench pattern, plasma etching using a gas containing a fluorocarbon based gas as a main component and plasma etching using a gas containing oxygen as a main component are alternately performed.

12. The pattern formation method according to claim 11, wherein the second radiation sensitive composition is made of a polymer compound resistant to oxygen that is present at the time of plasma etching, or the second radiation sensitive composition is higher in resistance to oxygen that is present at the time of plasma etching as compared to the first radiation sensitive composition.

13. The pattern formation method according to claim 11, wherein the forming of the hole pattern and the trench pattern includes
transferring the hole pattern onto the second mask film through the first resist pattern serving as a mask by performing the plasma etching using a gas containing a fluorocarbon based gas as a main component,
transferring the hole pattern onto the first mask film through the second mask film serving as a mask, and transferring the trench pattern onto the first resist pattern through the second resist pattern serving as a mask, by performing the plasma etching using a gas containing oxygen as a main component,
transferring the trench pattern onto the second mask film through the first resist pattern serving as a mask, and transferring the hole pattern onto the processing object film through the first mask film serving as a mask, by performing the plasma etching using a gas containing a fluorocarbon based gas as a main component,
transferring the trench pattern onto the first mask film through the second mask film and the first resist pattern both serving as a mask by performing the plasma etching using a gas containing oxygen as a main component, and
transferring the trench pattern onto the processing object film through the first mask film serving as a mask by performing the plasma etching using a gas containing a fluorocarbon based gas as a main component.

14. The pattern formation method according to claim 13, wherein, in the transferring of the hole pattern onto the processing object film, the plasma etching using a gas containing a fluorocarbon based gas as a main component is finished at a time point when the transferring of the trench pattern onto the second mask film is finished.

15. The pattern formation method according to claim 13, wherein, in the transferring of the hole pattern onto the processing object film, the plasma etching using a gas containing a fluorocarbon based gas as a main component is finished at a time point when the hole pattern reaches a lower surface of the processing object film.

16. The pattern formation method according to claim 14, wherein, in the transferring of the trench pattern onto the processing object film, the plasma etching using a gas containing a fluorocarbon based gas as a main component is finished at a time point when the hole pattern reaches a lower surface of the processing object film.

17. The pattern formation method according to claim 1, further comprising:
forming an organic mask film on the processing object film, before the forming of the first resist film; and
forming an hole pattern and a trench pattern connected to the hole pattern in the processing object film by plasma etching, after the forming of the second resist pattern,
wherein, in the forming of the hole pattern and the trench pattern, plasma etching using a gas containing a fluorocarbon based gas as a main component and plasma etching using a gas containing oxygen as a main component are alternately performed.

18. The pattern formation method according to claim 17, wherein the first radiation sensitive composition is made of a polymer compound resistant to oxygen that is present at the time of plasma etching, or the first radiation sensitive composition is higher in resistance to oxygen that is present at the time of plasma etching as compared to the second radiation sensitive composition.

19. The pattern formation method according to claim 18, wherein the forming of the hole pattern and the trench pattern includes
transferring the hole pattern onto the mask film through the first resist pattern serving as a mask by performing the plasma etching using a gas containing oxygen as a main component,
transferring the trench pattern onto the first resist pattern through the second resist pattern serving as a mask, and transferring the hole pattern onto the processing object film through the mask film serving as a mask by performing the plasma etching using a gas containing a fluorocarbon based gas as a main component,
transferring the trench pattern onto the mask film through the second resist pattern and the first resist pattern both serving as a mask by performing the plasma etching using a gas containing oxygen as a main component, and
transferring the trench pattern onto the processing object film through the first resist pattern and the mask film both serving as a mask by performing the plasma etching using a gas containing a fluorocarbon based gas as a main component.

20. The pattern formation method according to claim 11, further comprising, after the forming of the hole pattern and the trench pattern, embedding a conductive material in the hole pattern and the trench pattern.
